(19) United States
(12) Patent Application Publication
(10) Pub. No.: US 2025/0341542 A1
(43) Pub. Date: Nov. 6, 2025

(54) ELECTRICAL CONNECTOR

(71) Applicant: POINT ENGINEERING CO., LTD., Asan-si (KR)

(72) Inventors: Bum Mo AHN, Suwon-si (KR); Young Heum EOM, Anyang-si (KR); Sung Eun AHN, Suwon-si (KR)

(73) Assignee: POINT ENGINEERING CO., LTD., Asan-si (KR)

(21) Appl. No.: 19/198,138

(22) Filed: May 5, 2025

(30) Foreign Application Priority Data
May 3, 2024 (KR) 10-2024-0058942

(51) Int. Cl. G01R 1/067; H01R 13/24

(52) U.S. Cl. CPC G01R 1/06716; G01R 1/06733; G01R 1/06761; H01R 13/2428; H01R 13/2471; H01R 2201/20

(57) ABSTRACT

The present invention comprises a first contact part; a second contact part; and an elastic deformation part connecting the first contact part and the second contact part, wherein the first contact part and the second contact part are relatively displaceable along a length direction, the elastic deformation part has a shape folded in a width direction, and the elastic deformation part includes a plurality of divided parts, thereby providing an electrical connector that can reduce pin force while maintaining the strength of the elastic part. Additionally, the present invention provides an electrical connector that improves the reliability of inspection by ensuring that numerous electrical connectors provided in an inspection device can form and maintain the same current path when they are pressed and deformed.

### CROSS-REFERENCE TO RELATED APPLICATIONS

The present application claims priority to Korean Patent Application No. 10-2024-0058942, filed May 3, 2024, the entire contents of which is incorporated herein for all purposes by this reference.

### TECHNICAL FIELD

The present invention relates to an electrical connector.

### BACKGROUND

In objects to be inspected such as semiconductor devices, display panels, or cameras, continuity tests and operational characteristic tests are generally conducted during their manufacturing processes.

These tests are performed by connecting the electrodes of the object to be inspected with the inspection device using electrical connectors. The inspection device is equipped with numerous electrical connectors, ranging from hundreds to hundreds of thousands, corresponding to the number of electrodes of the object to be inspected.

As an example of such electrical connectors, there is one described in the Korean Patent No. 10-1911002 (hereinafter referred to as ‘prior art’). The prior art includes an elastic part that stretches along the length direction, a first contact part connected to the first end of the elastic part in the length direction, and a plate-shaped second contact part connected to the second end of the elastic part in the length direction. The elastic part has a plurality of band-shaped elastic pieces arranged with gaps between them. The plurality of belt-shaped elastic pieces allow the elastic part to deform more easily, thereby reducing the pin force.

However, the prior art has the following problems.

First, the elastic part of the prior art has a structure with a plurality of belt-shaped elastic pieces. While reducing the width of the elastic pieces can lower the pin force, it also causes a problem of reduced strength of the elastic part. Therefore, there is a need for a method that can lower the pin force while maintaining the strength of the elastic part.

Second, the prior art includes an inclined surface on the upper surface of the second contact part to prevent the first contact part and the second contact part from contacting each other when elastically deformed. This configuration of the inclined surface allows for additional overdrive (OD). However, even if additional overdrive (OD) is possible, it is not easy to uniformly control the degree of compression of the numerous electrical connectors. That is, depending on the degree of compression in each electrical connector, some electrical connectors may form a current path through the first contact part, the elastic part, and the second contact part without the first and second contact parts touching, while others may form a current path directly through the first and second contact parts by touching. If the current paths of the multiple electrical connectors in the inspection device are not uniform, the reliability of the inspection of the object to be inspected is compromised. Therefore, there is a need for a method to ensure that the current paths of the numerous electrical connectors are uniformly formed during inspection.

### PRIOR ART DOCUMENTS

### Patent Documents

(Patent Document 1) Korean Patent No. 10-1911002

### SUMMARY

The present invention was devised to solve the problems of the prior art described above, and its purpose is to provide an electrical connector that can reduce pin force while maintaining the strength of the elastic part.

Meanwhile, the present invention aims to provide an electrical connector that improves the reliability of testing by ensuring that numerous electrical connectors provided in a testing device can form and maintain the same current path when they are pressed and deformed.

To achieve the aforementioned objectives, the electrical connector according to the present invention comprises a first contact part; a second contact part; and an elastic deformation part connecting the first contact part and the second contact part; wherein the first contact part and the second contact part are relatively displaceable along a length direction, the elastic deformation part has a shape folded in a width direction, and the elastic deformation part includes a plurality of divided parts, each of the plurality of divided parts being connected to the first contact part and the second contact part, and each of the divided parts being spaced apart from each other in a thickness direction.

Additionally, the divided part has at least one or more slits penetrating in the thickness direction, and at least one of the slits extends into an interior of at least one of the first contact part and the second contact part.

Furthermore, the first contact part and the second contact part are provided with a plurality of metal layers stacked, and the divided part is provided with a single metal layer.

Moreover, the first contact part and the second contact part are provided with a single metal layer, and the divided part is provided with a single metal layer.

Additionally, the first contact part and the second contact part are provided with a plurality of metal layers stacked, and the divided part is provided with a plurality of metal layers stacked.

Meanwhile, the electrical connector according to the present invention comprises a first contact part; a second contact part; and an elastic deformation part connecting the first contact part and the second contact part; wherein the first contact part and the second contact part are relatively displaceable along a length direction, the elastic deformation part has a shape folded in a width direction, the first contact part has a first inclined surface on a lower surface facing the second contact part, the second contact part has a second inclined surface on an upper surface facing the first contact part, the first inclined surface and the second inclined surface are inclined in the same direction, and when the first contact part and the second contact part are relatively displaced in the length direction and the first inclined surface and the second inclined surface come into contact with each other, they maintain contact while sliding and moving to allow additional overdrive, and at the same time, the first inclined surface and the second inclined surface form a current path due to the contact.

Additionally, at least one of the first inclined surface and the second inclined surface is provided with an electrically conductive lubricating material layer.

Furthermore, the electrically conductive lubricating material layer can be selected from DLC (Diamond-Like Carbon), metal nitride layer (MNx), metal carbide layer (MCy), and metal boride layer (MBz), the metal can be selected from transition metals, and at this time, the x value is 0.5≤x≤1, the y value is 0.42≤y≤1, and the z value is 0.5≤z≤2.

Additionally, when the first inclined surface slides and moves with respect to the second inclined surface, a contact point of the first contact part and a contact point of the second contact part are relatively displaced in the width direction without tilting.

Moreover, the elastic deformation part includes a plurality of divided parts, each of the plurality of divided parts being connected to the first contact part and the second contact part, and each of the divided parts being spaced apart from each other in a thickness direction.

The present invention provides an electrical connector that can reduce pin force while maintaining the strength of the elastic part. Additionally, the present invention provides an electrical connector that improves the reliability of testing by ensuring that numerous electrical connectors provided in a testing device can form and maintain the same current path when they are pressed and deformed.

### BRIEF DESCRIPTION OF DRAWINGS

The above and other features of embodiments of the disclosure will become apparent by describing in detail embodiments thereof with reference to the accompanying drawings.

FIG. 1 is a perspective view of an electrical connector according to a preferred first embodiment of the present invention.

FIG. 2 is a front view of an electrical connector according to a preferred first embodiment of the present invention.

FIG. 3 is a rear perspective view of an electrical connector according to a preferred first embodiment of the present invention.

FIG. 4 is a rear view of an electrical connector according to a preferred first embodiment of the present invention.

FIG. 5 is a perspective view of an electrical connector according to a modified example of the preferred first embodiment of the present invention.

FIG. 6 is a perspective view of an electrical connector according to a preferred second embodiment of the present invention.

FIG. 7A is a front view showing a state before the first contact part and the second contact part of the electrical connector according to the second embodiment come into contact with each other.

FIG. 7B is a front view showing a state where the first contact part and the second contact

part of the electrical connector according to the second embodiment are in contact with each other.

FIG. 7C is a front view showing a state where the first contact part and the second contact part of the electrical connector according to the second embodiment are sliding while maintaining contact.

FIG. 8 is a perspective view of an electrical connector according to a first modified example of the preferred second embodiment of the present invention.

FIG. 9 is a perspective view of an electrical connector according to a second modified example of the preferred second embodiment of the present invention.

### DETAILED DESCRIPTION OF THE EMBODIMENTS

The following content merely illustrates the principles of the invention. Therefore, those skilled in the art can devise various devices that implement the principles of the invention and are included within the concept and scope of the invention, even if not explicitly described or shown in this specification. Additionally, all conditional terms and embodiments listed in this specification are intended, in principle, solely to aid in understanding the concept of the invention and should not be understood as limiting the specifically listed embodiments and conditions.

The above-mentioned objectives, features, and advantages will become more apparent through the following detailed description in conjunction with the accompanying drawings, enabling those skilled in the art to easily implement the technical idea of the invention.

The embodiments described in this specification will be explained with reference to ideal exemplary cross-sectional and/or perspective views of the invention. The thicknesses of the films and regions shown in these drawings are exaggerated for effective explanation of the technical content. The shapes in the exemplary drawings may be modified due to manufacturing techniques and/or tolerances. The embodiments of the invention are not limited to the specific forms shown but also include variations in shape generated according to the manufacturing process. The technical terms used in this specification are merely used to describe specific embodiments and are not intended to limit the invention. Singular expressions include plural expressions unless the context clearly indicates otherwise. In this specification, terms such as “comprising” or “including” are intended to specify the presence of features, numbers, steps, operations, components, parts, or combinations thereof described in this specification, and do not preclude the possibility of the presence or addition of one or more other features, numbers, steps, operations, components, parts, or combinations thereof.

Hereinafter, the preferred embodiments of the present invention will be described in detail with reference to the accompanying drawings. In describing various embodiments below, components performing the same function will be given the same names and reference numbers for convenience, even if the embodiments differ. Additionally, the configuration and operation already described in other embodiments will be omitted for convenience.

Hereinafter, the preferred embodiments of the present invention will be described in detail with reference to the accompanying drawings.

An electrical connector 100 according to a preferred embodiment of the present invention can be mounted on an inspection device and used to electrically and physically connect to an object to be inspected to transmit electrical signals.

The object to be inspected includes, but is not limited to, electronic devices or components such as semiconductor devices, display panels, or cameras. For example, the object to be inspected may include memory chips, microprocessor chips, logic chips, light-emitting devices, substrates, or combinations thereof. At least one of the objects to be inspected may be a logic LSI (such as ASIC, FPGA, and ASSP), microprocessor (such as CPU and GPU), memory (such as DRAM, HMC (Hybrid Memory Cube), MRAM (Magnetic RAM), PCM (Phase-Change Memory), ReRAM (Resistive RAM), FeRAM (Ferroelectric RAM), and flash memory (NAND flash)), semiconductor light-emitting devices (including LED, mini LED, micro LED, etc.), power devices, analog ICs (such as DC-AC converters and insulated gate bipolar transistors (IGBT)), MEMS (such as accelerometers, pressure sensors, vibrators, and gyro sensors), wireless devices (such as GPS, FM, NFC, RFEM, MMIC, and WLAN), discrete devices, BSI, CIS, camera modules, CMOS, passive devices, GAW filters, RF filters, RF IPD, APE, and BB. Additionally, the object to be inspected may be a semiconductor wafer state or a packaged semiconductor device.

The width direction of the electrical connector 100 described below is the ±x direction indicated in the drawings, the length direction of the electrical connector 100 is the ty direction indicated in the drawings, and the thickness direction of the electrical connector 100 is the ±z direction indicated in the drawings.

### Electrical Connector 100 According to the First Embodiment

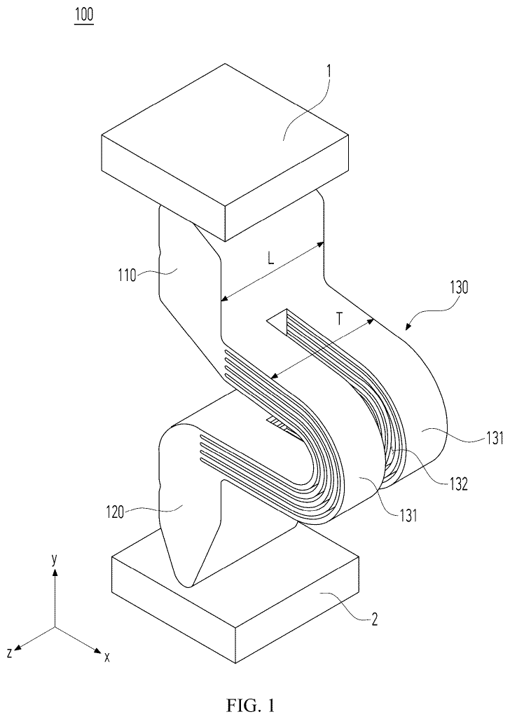

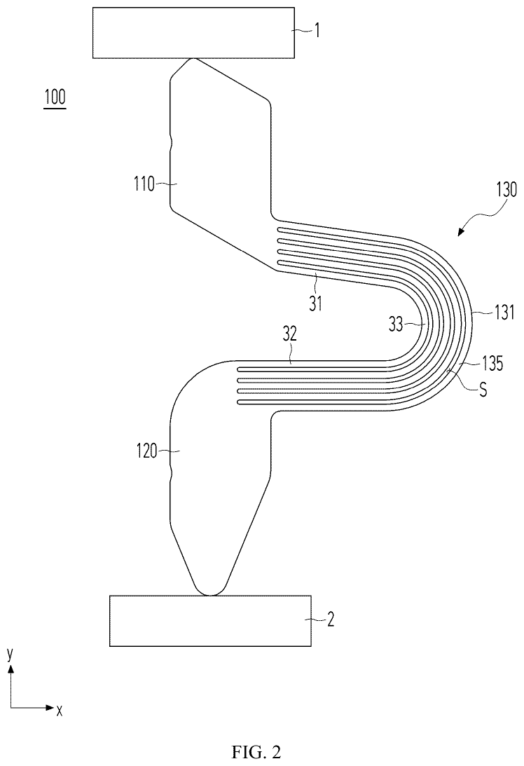

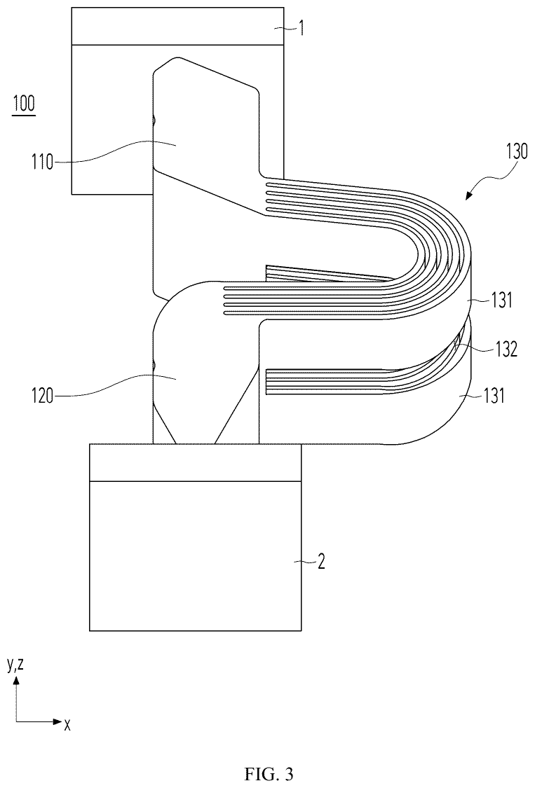

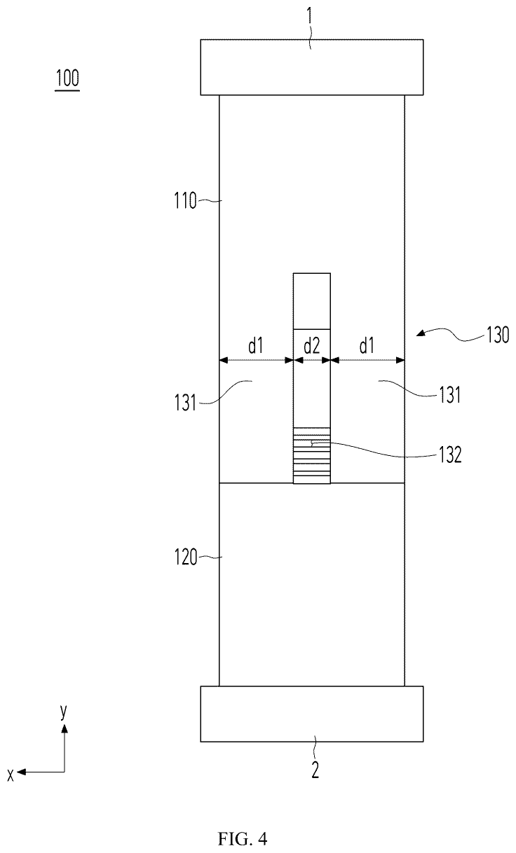

FIG. 1 is a perspective view of an electrical connector 100 according to a preferred first embodiment of the present invention, FIG. 2 is a front view of the electrical connector 100 according to a preferred first embodiment of the present invention, FIG. 3 is a rear perspective view of the electrical connector 100 according to a preferred first embodiment of the present invention, and FIG. 4 is a rear view of the electrical connector 100 according to a preferred first embodiment of the present invention.

The electrical connector 100 comprises a first contact part 110, a second contact part 120, and an elastic deformation part 130 connecting the first contact part 110 and the second contact part 120.

The first contact part 110 and the second contact part 120 are relatively displaceable along the length direction (±y direction) by the elastic deformation part 130. The first contact part 110 can contact a first object 1, and the second contact part 120 can contact a second object 2. Here, one of the first object 1 and the second object 2 corresponds to the object to be inspected, and the other corresponds to a circuit part for inspecting the object to be inspected.

The first contact part 110 and the second contact part 120 have a thickness L in the

thickness direction (±z direction). The first contact part 110 and the second contact part 120 have the same thickness L in the thickness direction (±z direction).

The elastic deformation part 130 has a shape folded in the width direction. The elastic deformation part 130 includes a plurality of divided parts 131, each of the plurality of divided parts 131 being connected to the first contact part 110 and the second contact part 120, and each of the divided parts 131 being spaced apart from each other in the thickness direction.

Each of the divided parts 131 has the same cross-sectional shape in the x-y plane. Meanwhile, each of the divided parts 131 can have the same elastic modulus.

The elastic deformation part 130 includes a plurality of divided parts 131 and a space part 132 provided between the plurality of divided parts 131. The space part 132 is provided between the plurality of divided parts 131. The plurality of divided parts 131 are spaced apart from each other with the space part 132 in between.

The elastic deformation part 130 is provided with a plurality of divided parts 131 divided into n parts in the thickness direction (±z direction) (where n is a natural number of 2 or more).

One end of each divided part 131 is continuous with the first contact part 110 on the side of the first contact part 110, and the other end of each divided part 131 is continuous with the second contact part 120 on the side of the second contact part 120. Therefore, the plurality of divided parts 131 are connected in parallel to the first contact part 110 and the second contact part 120.

The length L in the thickness direction (±z direction) of the first contact part 110 and the second contact part 120 is formed to be the same length as the length T in the thickness direction (±z direction) of the elastic deformation part 130. The length L in the thickness direction (±z direction) of the first contact part 110 and the second contact part 120 is longer than the sum of the lengths d1 in the thickness direction (±z direction) of the plurality of divided parts 131.

The length d1 in the thickness direction (±z direction) of the divided part 131 can be formed longer than the length d2 in the thickness direction (±z direction) of the space part 132. In other words, the length dl in the thickness direction (±z direction) of the divided part 131 can be formed longer than the length of the space between the divided parts 131.

The lengths d1 in the thickness direction (±z direction) of the plurality of divided parts 131 can be the same. However, it is not limited to this, and the lengths dl in the thickness direction (±z direction) of the plurality of divided parts 131 can be different from each other.

The elastic deformation part 130 includes a plurality of divided parts 131 and a space part 132 provided between the plurality of divided parts 131, and the sum of the lengths dl in the thickness direction (±z direction) of the plurality of divided parts 131 is formed shorter than the length L in the thickness direction (±z direction) of the first contact part 110 and the second contact part 120, thereby reducing the pin force without the need to reduce the width of the elastic piece 135. In other words, it is possible to reduce the pin force while maintaining the strength of the elastic deformation part 130.

Each of the divided parts 131 is provided with at least one slit s penetrating in the thickness direction (±z direction). Each of the divided parts 131 has a plurality of band-shaped elastic pieces 135 arranged with the slit s in between. Each elastic piece 135 includes a first straight part 31 connected to the first contact part 110, a second straight part 32 connected to the second contact part 120, and a curved part 33 connecting the first straight part 31 and the second straight part 32.

At least one slit s extends into the interior of at least one of the first contact part 110 and the second contact part 120. That is, at least one slit s is provided in the divided part 131 and can extend into the interior of at least one of the first contact part 110 and the second contact part 120. Through this configuration, it is possible to form the length of the elastic piece 135 longer, making the deformation of the divided part 131 easier, thus being more effective in reducing pin force. Additionally, this configuration can improve the rigidity of the elastic piece 135. In areas where the area changes abruptly, stress concentration can lead to breakage. Considering the drawings, in the case of the elastic piece 135 located at the outermost part among the plurality of elastic pieces 135, it has a more gradual area change at the beginning of its end, thereby resolving the stress concentration issue.

The lower surface of the first contact part 110 is composed of an inclined plane, and the upper surface of the second contact part 120 is composed of a curved surface with curvature.

According to this configuration, if there is additional pressing force after the first contact part 110 and the second contact part 120 come into contact with each other, the first contact part 110 and the second contact part 120 can tilt while making line contact.

The first contact part 110 and the second contact part 120 are provided with a plurality of metal layers stacked, and the divided part 131 can be provided with a single metal layer.

The first contact part 110 and the second contact part 120 are provided with a plurality of metal layers stacked in the thickness direction (±z direction) of the electrical connector 100. The plurality of metal layers include a first metal layer and a second metal layer. The first metal layer is a metal with relatively high rigidity or wear resistance compared to the second metal layer, preferably formed of rhodium (Rd), platinum (Pt), iridium (Ir), palladium (Pd), nickel (Ni), manganese (Mn), tungsten (W), phosphorus (Ph) or their alloys, or palladium-cobalt (PdCo) alloy, palladium-nickel (PdNi) alloy, nickel-phosphorus (NiPh) alloy, nickel-manganese (NiMn), nickel-cobalt (NiCo) or nickel-tungsten (NiW) alloy. The second metal layer is a metal with relatively high electrical conductivity compared to the first metal layer, preferably formed of copper (Cu), silver (Ag), gold (Au) or their alloys. Here, the stacked plurality of first metal layers can be the same or different metals. Also, the stacked plurality of second metal layers can be the same or different metals. The first metal layer is provided on the lower and upper surfaces of the first contact part 110 and the second contact part 120 in the thickness direction (±z direction), and the second metal layer is provided between the first metal layers 110. For example, the first contact part 110 and the second contact part 120 are alternately stacked in the order of the first metal layer, the second metal layer, and the first metal layer, and the number of stacked layers can be three or more.

The divided part 131 can be provided with a single metal layer, unlike the first contact part 110 and the second contact part 120. Here, the divided part 131 can be formed of the first metal layer and can be formed of the same metal as the first metal layer formed on the first contact part 110 and the second contact part 120.

For example, the first contact part 110 and the second contact part 120 are formed by stacking in the order of palladium-cobalt (PdCo) alloy, gold (Au), and palladium-cobalt (PdCo) alloy, and all of the plurality of divided parts 131 can be formed of palladium-cobalt (PdCo) alloy. Alternatively, the first contact part 110 and the second contact part 120 are formed by stacking in the order of palladium-cobalt (PdCo) alloy, copper (Cu), and nickel-cobalt (NiCo) alloy, and one of the plurality of divided parts 131 can be formed of palladium-cobalt (PdCo) alloy, and the other can be formed of nickel-cobalt (NiCo) alloy.

Meanwhile, the first contact part 110 and the second contact part 120 can be provided with a single metal layer, and the divided part 131 can be provided with a single metal layer. In this case, the first contact part 110, the second contact part 120, and the divided part 131 can be formed of the first metal layer. For example, the first contact part 110, the second contact part 120, and the divided part 131 can be formed of palladium-cobalt (PdCo) alloy or nickel-cobalt (NiCo) alloy.

Meanwhile, the first contact part 110 and the second contact part 120 are provided with a plurality of metal layers stacked in the thickness direction (±z direction) of the electrical connector 100, and the divided part 131 can be provided with a plurality of metal layers stacked in the thickness direction (±z direction) of the electrical connector 100. The plurality of metal layers include a first metal layer and a second metal layer. The metal layer formed in the divided part 131 can be continuously formed of the same metal as the metal layer formed in the first contact part 110 and the second contact part 120.

### Electrical Connector 100 According to a Modification of the First Embodiment

Next, a modification of the first embodiment according to the present invention will be described. However, the modifications described below will be explained focusing on the characteristic components compared to the first embodiment, and the description of the same or similar components as the first embodiment will be omitted as much as possible.

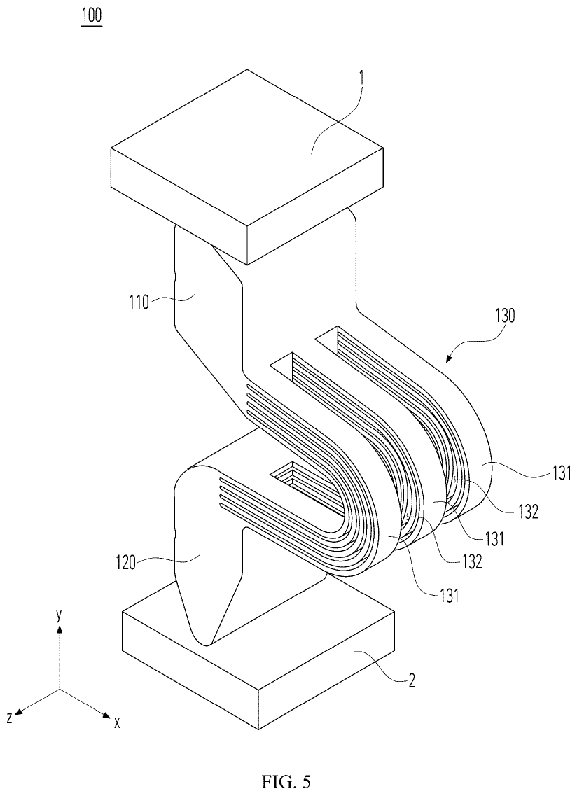

Hereinafter, an electrical connector 100 according to a modification of the first embodiment of the present invention will be described with reference to FIG. 5.

FIG. 5 is a perspective view of an electrical connector 100 according to a modification of the first embodiment of the present invention.

The modification of the first embodiment differs from the structure shown in the drawings of the first embodiment in that it includes a plurality of space parts 132, and the rest of the configuration is the same as the configuration of the first embodiment described above. In FIG. 5, the space parts 132 are illustrated as being two, but the number of space parts 132 is not limited to this.

### Electrical Connector 100 According to the Second Embodiment

Next, a second embodiment according to the present invention will be described. However, the second embodiment described below will be explained focusing on the characteristic components compared to the first embodiment, and the description of the same or similar components as the first embodiment will be omitted as much as possible.

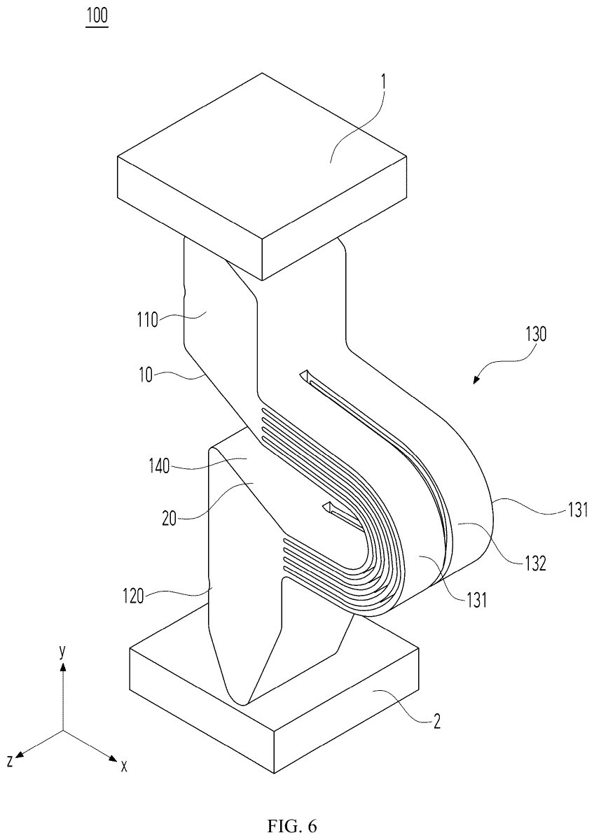

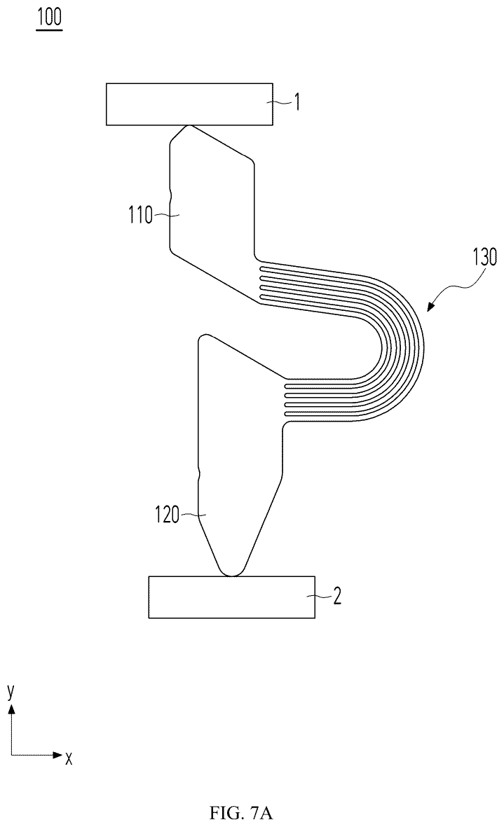

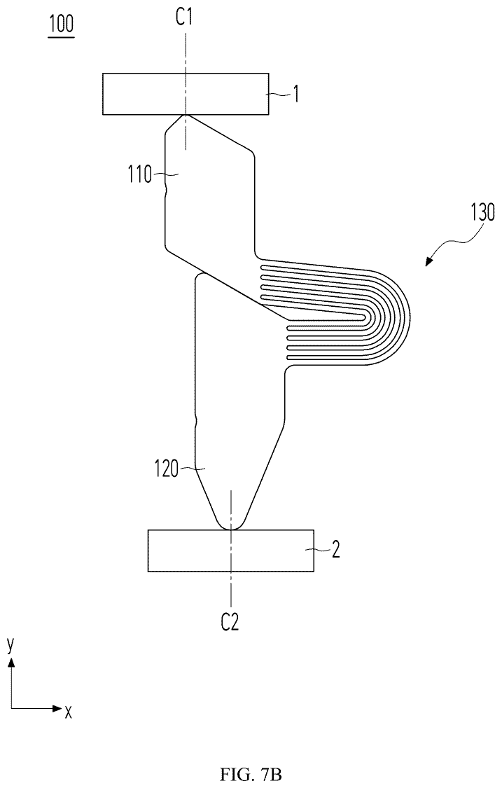

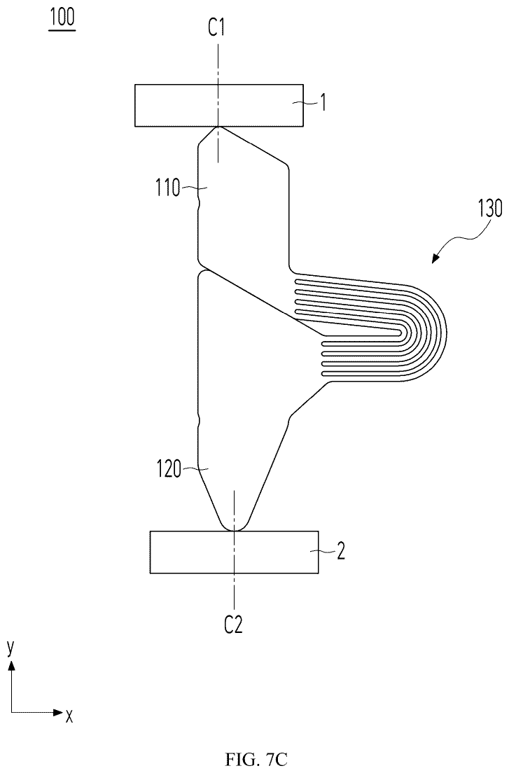

Hereinafter, an electrical connector 100 according to the second embodiment of the present invention will be described with reference to FIGS. 6 to 7C.

FIG. 6 is a perspective view of an electrical connector 100 according to the second embodiment of the present invention, FIG. 7A is a front view showing a state before the first contact part 110 and the second contact part 120 of the electrical connector 100 according to the second embodiment come into contact with each other, FIG. 7B is a front view showing a state where the first contact part 110 and the second contact part 120 of the electrical connector 100 according to the second embodiment are in contact with each other, and FIG. 7C is a front view showing a state where the first contact part 110 and the second contact part 120 of the electrical connector 100 according to the second embodiment maintain contact and slide.

The electrical connector 100 comprises a first contact part 110, a second contact part 120, and an elastic deformation part 130 connecting the first contact part 110 and the second contact part 120.

The first contact part 110 and the second contact part 120 are relatively displaceable along the length direction (±y direction) by the elastic deformation part 130. The first contact part 110 can contact the first object 1, and the second contact part 120 can contact the second object 2. The first contact part 110 and the second contact part 120 have a thickness L in the thickness direction (±z direction).

To ensure inspection reliability for the test object during the overdrive (OD) process, first, the pin force of the electrical connector 100 should be small so that the lower surface of the first contact part 110 and the upper surface of the second contact part 120 of all the electrical connectors 100 can more easily make surface contact, and second, the first contact part 110 and the second contact part 120 should be relatively displaced in the length direction (±y direction) in response to additional overdrive (OD) while maintaining surface contact between the lower surface of the first contact part 110 and the upper surface of the second contact part 120.

First, to reduce the pin force, the elastic deformation part 130 comprises a plurality of divided parts 131 and space part 132 provided between the plurality of divided parts 131. The space part 132 is provided between the plurality of divided parts 131. The plurality of divided parts 131 are provided spaced apart from each other with the space part 132 in between.

The elastic deformation part 130 has a shape folded in the width direction. The elastic deformation part 130 includes a plurality of divided parts 131, each of the plurality of divided parts 131 being connected to the first contact part 110 and the second contact part 120, and each of the divided parts 131 being spaced apart from each other in the thickness direction.

The elastic deformation part 130 includes a plurality of divided parts 131, each of the plurality of divided parts 131 being connected to the first contact part 110 and the second contact part 120, and each of the divided parts 131 being spaced apart from each other in the thickness direction (±z direction). Through this configuration, it is possible to lower the pin force while maintaining the strength of the elastic deformation part 130.

Next, to allow the first contact part 110 and the second contact part 120 to be relatively displaced in the length direction (±y direction) in response to additional overdrive (OD) while maintaining surface contact between the lower surface of the first contact part 110 and the upper surface of the second contact part 120, the lower surface of the first contact part 110 is provided with a first inclined surface 10, and the upper surface of the second contact part 120 is provided with a second inclined surface 20.

The first contact part 110 is provided with a first inclined surface 10 on the lower surface facing the second contact part 120, and the second contact part 120 is provided with a second inclined surface 20 on the upper surface facing the first contact part 110.

The first inclined surface 10 and the second inclined surface 20 are formed as inclined planes sloping in the same direction. Based on the drawings, the first inclined surface 10 is formed as an inclined plane sloping downward to the right, and the second inclined surface 20 is also formed as an inclined plane sloping downward to the right. The inclination angles of the first inclined surface 10 and the second inclined surface 20 are formed at the same angle. Therefore, when the first inclined surface 10 and the second inclined surface 20 come into contact with each other, they make contact plane to plane.

FIG. 7A shows a state before the first contact part 110 and the second contact part 120 come into contact with each other, FIG. 7B shows a state where the first contact part 110 and the second contact part 120 are in contact with each other, and FIG. 7C shows a state where the first contact part 110 and the second contact part 120 have slid while maintaining contact. FIG. 7B shows an overdrive (OD) of a first distance, and FIG. 7C shows an overdrive (OD) of a second distance. Here, the first distance is, for example, 100 um, and the second distance is 200 um. However, the values of the first and second distances are not limited to these and may vary depending on the type of the object to be inspected and the configuration of the surrounding devices.

Referring to FIGS. 7A and 7B, due to the pressing force, the first contact part 110 and the second contact part 120 are relatively displaced along the length direction (±y direction) until the lower surface of the first contact part 110 and the upper surface of the second contact part 120 come into contact with each other. In other words, by proceeding with an overdrive (OD) of the first distance, the lower surface of the first contact part 110 and the upper surface of the second contact part 120 come into contact with each other. When the lower surface of the first contact part 110 and the upper surface of the second contact part 120 come into contact with each other, the first inclined surface 10 and the second inclined surface 20 make surface contact with each other.

Referring to FIGS. 7A and 7B, if an additional overdrive (OD) of the second distance is performed, the first inclined surface 10 and the second inclined surface 20 maintain contact while the first contact part 110 slides relative to the second contact part 120. From the point when the lower surface of the first contact part 110 comes into contact with the upper surface of the second contact part 120, the lower surface of the first contact part 110 and the upper surface of the second contact part 120 maintain contact during the additional overdrive (OD) process. Furthermore, from the point when the lower surface of the first contact part 110 comes into contact with the upper surface of the second contact part 120, the current path is formed directly from the first contact part 110 to the second contact part 120 without passing through the elastic deformation part 130 during the additional overdrive (OD) process.

As such, the electrical connector 100 allows the first contact part 110 and the second contact part 120 to be relatively displaced in the length direction (±y direction) so that the first inclined surface 10 and the second inclined surface 20 come into contact with each other, maintaining contact while sliding to allow additional overdrive, and at the same time, the first inclined surface 10 and the second inclined surface 20 form a current path due to the contact. At this time, since the elastic deformation part 130 is composed of a plurality of divided parts 131, the pin force is small, making it easy to maintain the contact state of the first inclined surface 10 and the second inclined surface 20.

The inspection device is equipped with numerous electrical connectors 100, ranging from hundreds to hundreds of thousands, corresponding to the number of electrode parts of the object to be inspected. However, due to manufacturing tolerances, assembly tolerances, and height variations of the electrode parts of the object to be inspected, deviations occur in the contact between each electrical connector 100 and the electrode parts. In other words, among the multiple electrical connectors 100, some electrical connectors 100 are compressed within the normal range, while other electrical connectors 100 may be excessively compressed. Depending on the degree of compression, some of the multiple electrical connectors 100 may not have the first contact part 110 and the second contact part 120 in contact, forming a current path from the first contact part 110 through the elastic deformation part 130 to the second contact part 120, while the rest of the electrical connectors 100 may have the first contact part 110 and the second contact part 120 in contact, forming a current path directly from the first contact part 110 to the second contact part 120. In such cases, the current paths of the multiple electrical connectors 100 are not the same, leading to a decrease in the reliability of the inspection.

However, according to the configuration of the electrical connector 100 according to the preferred second embodiment of the present invention, the above problems are solved. If the inspection device applies an overdrive (OD) of more than the first distance to the electrical connectors 100, the first inclined surface 10 of the first contact part 110 and the second inclined surface 20 of the second contact part 120 maintain contact while sliding. Therefore, all the electrical connectors 100 provided in the inspection device form a current path directly from the first contact part 110 to the second contact part 120, so the reliability of the inspection of the object to be inspected is not reduced. Also, since the current flows directly from the first contact part 110 to the second contact part 120 without passing through the elastic deformation part 130, the current path is shortened, making it more effective for inspecting high-frequency objects to be inspected.

Meanwhile, when the first inclined surface 10 slides relative to the second inclined surface 20, the contact point of the first contact part 110 in contact with the first object 1 and the contact point of the second contact part 120 in contact with the second object 2 are relatively displaced in the width direction (±x direction) without tilting. In other words, the contact point of the first contact part 110 and the contact point of the second contact part 120 are relatively displaced in a direction where the centerline C1 of the contact point of the first contact part 110 and the centerline C2 of the contact point of the second contact part 120 come closer to each other. Through the approach movement of the contact point of the first contact part 110 and/or the contact point of the second contact part 120 in the width direction (±x direction), it is possible to remove the oxide film on the surface of the first and second objects 1 and 2.

If the contact point of the first contact part 110 and/or the contact point of the second contact part 120 tilts, there is a problem that the surface of the first and second objects 1 and 2 is dented. However, if the contact point of the first contact part 110 and/or the contact point of the second contact part 120 moves in the width direction (±x direction) without tilting, although there may be a movement distance in the width direction (±x direction) of the contact point of the first contact part 110 and/or the contact point of the second contact part 120, it is possible to solve the problem of the surface of the first and second objects 1 and 2 being dented.

At least one of the first inclined surface 10 and the second inclined surface 20 is provided with an electrically conductive lubricating material layer 140. The electrically conductive lubricating material layer 140 is formed of a material with excellent electrical conductivity and lubricating properties, ensuring electrical conductivity and maintaining lubricating properties even when the first inclined surface 10 and the second inclined surface 20 slide, allowing the first contact part 110 and the second contact part 120 to slide more easily. Also, since a material with a low friction coefficient is formed on at least one of the first inclined surface 10 and the second inclined surface 20, the pin force can be further reduced.

The electrically conductive lubricating material layer 140 can be selected from DLC (Diamond-Like Carbon), metal nitride layer (MNx), metal carbide layer (MCy), and metal boride layer (MBz), and the metal can be selected from transition metals, with x being 0.5≤x≤1, y being 0.42≤y≤1, and z being 0.5≤z≤2. The electrically conductive lubricating material layer 140 selected from the metal nitride layer (MNx), metal carbide layer (MCy), and metal boride layer (MBz) can be formed using chemical vapor deposition, physical vapor deposition such as sputtering, or arc ion plating, but is not limited thereto. The electrically conductive lubricating material layer 140 can be provided on at least one of the first inclined surface 10 and the second inclined surface 20, and can also be provided on the entire surface of the electrical connector 100.

Unlike the prior art, the preferred second embodiment of the present invention improves the reliability of the inspection of the object to be inspected by making it easier for the lower surface of the first contact part 110 and the upper surface of the second contact part 120 to come into contact during the overdrive (OD) process, while maintaining the contact state of the first inclined surface 10 of the first contact part 110 and the second inclined surface 20 of the second contact part 120.

### Electrical Connector 100 According to the First Modification of the Second Embodiment

Next, the first modification of the second embodiment according to the present invention will be described. However, the first modification described below will be explained focusing on the characteristic components compared to the second embodiment, and the description of the same or similar components as the second embodiment will be omitted as much as possible.

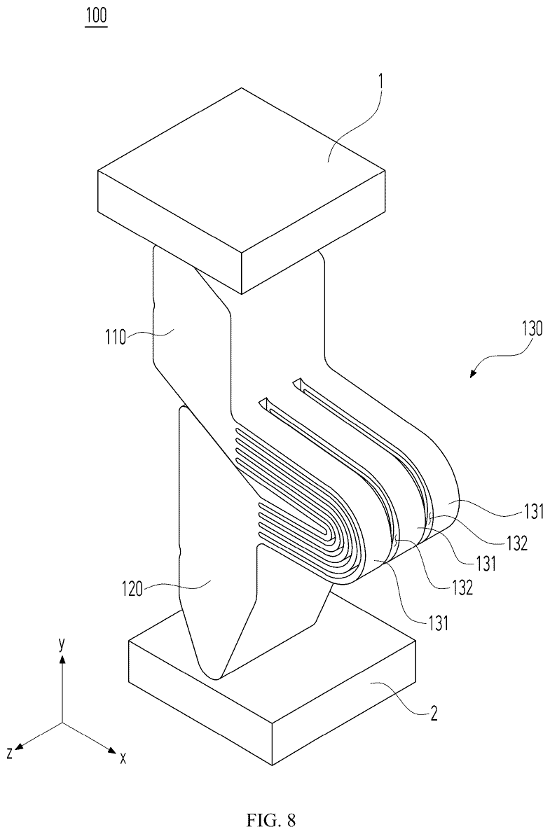

Hereinafter, the electrical connector 100 according to the first modification of the second embodiment of the present invention will be described with reference to FIG. 8.

FIG. 8 is a perspective view of the electrical connector 100 according to the first modification of the second embodiment of the present invention.

The electrical connector 100 comprises a first contact part 110, a second contact part 120, and an elastic deformation part 130 connecting the first contact part 110 and the second contact part 120.

The first contact part 110 and the second contact part 120 are relatively displaceable along the length direction (±y direction) by the elastic deformation part 130. The first contact part 110 can contact the first object 1, and the second contact part 120 can contact the second object 2. The first contact part 110 and the second contact part 120 have a thickness L in the thickness direction (±z direction).

The elastic deformation part 130 has a shape folded in the width direction. The elastic deformation part 130 includes a plurality of divided parts 131, each of the plurality of divided parts 131 being connected to the first contact part 110 and the second contact part 120, and each of the divided parts 131 being spaced apart from each other in the thickness direction.

The elastic deformation part 130 includes a plurality of divided parts 131, each of the plurality of divided parts 131 being connected to the first contact part 110 and the second contact part 120, and each of the divided parts 131 being spaced apart from each other in the thickness direction.

The elastic deformation part 130 includes a plurality of divided parts 131 and a space part 132 provided between the plurality of divided parts 131. The space part 132 is provided between the plurality of divided parts 131. The plurality of divided parts 131 are spaced apart from each other with the space part 132 in between.

The first modification of the second embodiment differs from the structure shown in the drawings of the second embodiment in that it includes a plurality of space parts 132, and the rest of the configuration is the same as that of the second embodiment described above. Meanwhile, in FIG. 8, it is illustrated that there are two space parts 132, but the number of space parts 132 is not limited to this.

### Electrical Connector 100 According to the Second Modification of the Second Embodiment

Next, the second modification of the second embodiment according to the present invention will be described. However, the second modification described below will be explained focusing on the characteristic components compared to the second embodiment, and the description of the components that are the same or similar to those of the second embodiment will be omitted as much as possible.

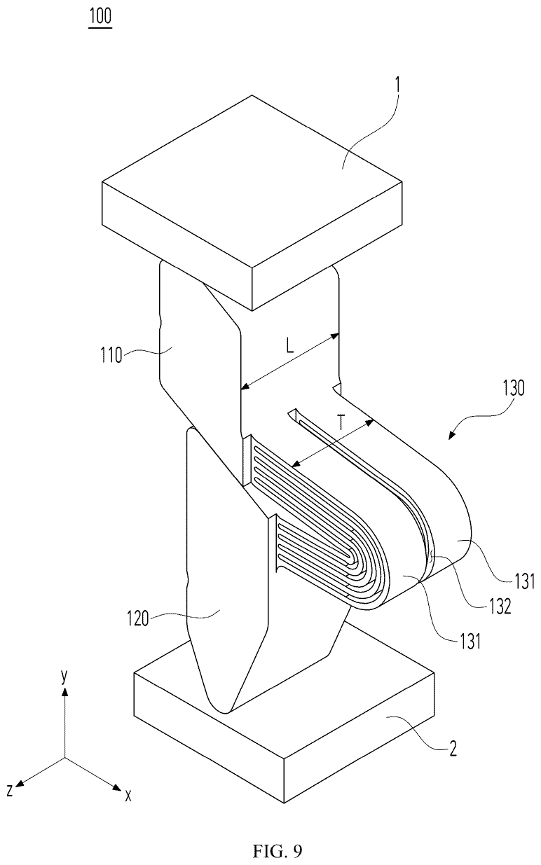

Hereinafter, an electrical connector 100 according to the second modification of the second embodiment of the present invention will be described with reference to FIG. 9.

FIG. 9 is a perspective view of an electrical connector 100 according to the second modification of the second embodiment of the present invention.

The electrical connector 100 includes a first contact part 110, a second contact part 120, and an elastic deformation part 130 connecting the first contact part 110 and the second contact part 120.

The first contact part 110 and the second contact part 120 are relatively displaceable along the length direction (±y direction) by the elastic deformation part 130. The first contact part 110 can contact the first object 1, and the second contact part 120 can contact the second object 2. The first contact part 110 and the second contact part 120 have a thickness L in the thickness direction (±z direction).

The elastic deformation part 130 has a shape folded in the width direction. The elastic deformation part 130 includes a plurality of divided parts 131, each of the plurality of divided parts 131 being connected to the first contact part 110 and the second contact part 120, and each of the divided parts 131 being spaced apart from each other in the thickness direction.

The elastic deformation part 130 includes a plurality of divided parts 131, each of the plurality of divided parts 131 being connected to the first contact part 110 and the second contact part 120, and each of the divided parts 131 being spaced apart from each other in the thickness direction.

The elastic deformation part 130 includes a plurality of divided parts 131 and a space part 132 provided between the plurality of divided parts 131. The space part 132 is provided between the plurality of divided parts 131. The plurality of divided parts 131 are spaced apart from each other with the space part 132 in between.

The first modification of the second embodiment differs from the structure shown in the drawings of the second embodiment in that the length L in the thickness direction (±z direction) of the first contact part 110 and the second contact part 120 is longer than the length T in the thickness direction (±z direction) of the elastic deformation part 130, and the rest of the configuration is the same as that of the second embodiment described above.

When the first contact part 110 and the second contact part 120 are relatively displaced along the length direction (±y direction), the front and rear surfaces in the thickness direction (±z direction) of the first contact part 110 and the second contact part 120 can contact the guide housing (not shown). However, through the configuration in which the length T in the thickness direction (±z direction) of the elastic deformation part 130 is formed shorter than the length L in the thickness direction (±z direction) of the first contact part 110 and the second contact part 120, the front and rear surfaces in the thickness direction (±z direction) of the elastic deformation part 130 do not contact the guide housing (not shown). Since the front and rear surfaces in the thickness direction (±z direction) of the elastic deformation part 130 are elastically deformed without contacting the guide housing (not shown), the pin force can be further reduced.

As described above, although the preferred embodiments of the present invention have been described with reference to the accompanying drawings, those skilled in the art can variously modify or change the present invention without departing from the spirit and scope of the present invention as set forth in the following claims.

What is claimed is:

1. An electrical connector comprising:
a first contact part;
a second contact part; and
an elastic deformation part connecting the first contact part and the second contact part;
wherein the first contact part and the second contact part are relatively displaceable along a length direction,
the elastic deformation part has a shape folded in a width direction, and
the elastic deformation part includes a plurality of divided parts, each of the plurality of divided parts being connected to the first contact part and the second contact part, and each of the divided parts being spaced apart from each other in a thickness direction.

2. The electrical connector of claim 1, wherein
the divided part has at least one or more slits penetrating in the thickness direction, and
at least one of the slits extends into an interior of at least one of the first contact part and the second contact part.

3. The electrical connector of claim 1, wherein
the first contact part and the second contact part are provided with a plurality of metal layers stacked, and
the divided part is provided with a single metal layer.

4. The electrical connector of claim 1, wherein
the first contact part and the second contact part are provided with a single metal layer, and
the divided part is provided with a single metal layer.

5. The electrical connector of claim 1, wherein
the first contact part and the second contact part are provided with a plurality of metal layers stacked, and
the divided part is provided with a plurality of metal layers stacked.

6. An electrical connector comprising:
a first contact part;
a second contact part; and
an elastic deformation part connecting the first contact part and the second contact part;
wherein the first contact part and the second contact part are relatively displaceable along a length direction,
the elastic deformation part has a shape folded in a width direction,
the first contact part has a first inclined surface on a lower surface facing the second contact part,
the second contact part has a second inclined surface on an upper surface facing the first contact part,
the first inclined surface and the second inclined surface are inclined in the same direction, and
when the first contact part and the second contact part are relatively displaced in the length direction and the first inclined surface and the second inclined surface come into contact with each other, they maintain contact while sliding and moving to allow additional overdrive, and at the same time, the first inclined surface and the second inclined surface form a current path due to the contact.

7. The electrical connector of claim 6, wherein
at least one of the first inclined surface and the second inclined surface is provided with an electrically conductive lubricating material layer.

8. The electrical connector of claim 6, wherein
the electrically conductive lubricating material layer can be selected from DLC (Diamond-Like Carbon), metal nitride layer (MNx), metal carbide layer (MCy), and metal boride layer (MBz), the metal can be selected from transition metals, and at this time, the x value is 0.55≤x≤1, the y value is 0.42≤y≤1, and the z value is 0.5≤z<2.

9. The electrical connector of claim 6, wherein
when the first inclined surface slides and moves with respect to the second inclined surface, a contact point of the first contact part and a contact point of the second contact part are relatively displaced in the width direction without tilting.

10. The electrical connector of claim 6, wherein
the elastic deformation part includes a plurality of divided parts, each of the plurality of divided parts being connected to the first contact part and the second contact part, and each of the divided parts being spaced apart from each other in a thickness direction.
